(19) United States
(12) Patent Application Publication
(10) Pub. No.: US 2012/0106099 A1
(43) Pub. Date: May 3, 2012

(54) PACKAGING BOARD

(75) Inventor: Yukinori KITA, Yokkaichi-city (JP)

(73) Assignee: SUMITOMO WIRING SYSTEMS, LTD., Yokkaichi-city (JP)

(21) Appl. No.: 13/281,878

(22) Filed: Oct. 26, 2011

(30) Foreign Application Priority Data
Nov. 2, 2010 (JP) 2010-246664

(51) Int. Cl. H05K 7/00

(52) U.S. Cl. 361/748

(57) ABSTRACT

A packaging board is described having a structure that can positively prevent same kind electrical components having different specifications from being erroneously mounted on a printed board and that can quickly confirm a regular packaging position for each of the same kind of electrical components. The packing board includes at least two electrical components having a same kind and different specifications from each other can be provided with component side identifying marks that can discriminate between the electrical components. A printed board can be provided with mounting areas for the same kind of electrical components with board side identifying marks that correspond to the component side identifying marks.

### CROSS REFERENCE TO RELATED APPLICATIONS

This application claims priority to JP 2010-246664 filed in Japan on Nov. 2, 2010, the entire disclosure of which is hereby incorporated by reference herein in its entirety.

### BACKGROUND

Exemplary embodiments of this disclosure relate to a packaging board in which a plurality of electrical components are mounted on a printed board.

In a packaging board, a plurality of electrical components such as relays and transformers can be mounted on a printed board and lead elements of the electrical components can be connected to printed circuits by soldering or the like. Such a packaging board can be contained in an electrical junction box or the like in a motor vehicle to constitute internal circuits. The packaging board can control a power supply or the like to various kinds of electrical package parts, for example, in response to electrical signals from a control system.

In a packaging board on which a plurality of electrical components are mounted, in order to prevent the various kinds of electrical components from being erroneously attached to the printed board and to enhance workability, silk-screened frame lines can be marked on the printed board to indicate mounting positions for the various kinds of electrical components. The number or the like of the electrical components can be described near the mounting positions by the silk screening. These marks or signs are disclosed in, for example, JP HEI 10 (1998)-190171 A or JP HEI 10 (1998)-190172 A. It is possible for the marks or the signs to indicate the electrical components on the printed board so that a working person can confirm the mounting positions for the various kinds of electrical components, thereby preventing erroneous attachment of the electrical components.

### SUMMARY

However, since only the mounting positions or the number for the electrical components are described on the printed board in the above-described packaging board, it can still be difficult to discriminate the mounting positions in the case of similar configurations of electrical components or in the case of many electrical components. This can cause erroneous attachment. In particular, the same kind electrical components (e.g., where positions of their lead elements are the same and their whole configurations are the same or similar while their specifications such as current values are different) can be mounted on the printed board wherever the positions of through-holes, into which the lead elements of the components are inserted, are the same. Consequently, there might be a high probability of erroneous attachment. Accordingly, it is difficult for the above-described marks alone to easily and positively prevent the same kind electrical components having different specifications from being erroneously mounted on the printed board.

In view of the above problems, aspects of this disclosure include providing a packaging board having a new structure that can positively prevent same kind electrical components having different specifications from being erroneously mounted on a printed board and that can quickly confirm a regular packaging position for each of the same kind of electrical components, thereby performing excellent workability.

In one aspect, this disclosure provides a packaging board in which a plurality of electrical components can be mounted on a printed board. The plural electrical components may include at least two electrical components having a same kind and having different specifications from each other. The same kind electrical components can be provided with component side identifying marks that can discriminate between the components. The printed board can be provided on mounting areas for the same kind electrical components with board side identifying marks that correspond to the component side identifying marks.

In exemplary embodiments, the regular mounting positions for the same kind electrical components can be quickly confirmed by verifying the component side identifying mark provided on each of the same kind electrical components against the board side identifying mark provided on the printed board without necessarily referring to a circuit wiring diagram. The same kind electrical components can generally include electrical components in which configurations are so similar thatit can be difficult to discriminate the components from each other at a glance. The same kind electrical components can include not only electrical component that have the same configurations as each other but also electrical components that have similar configurations to each other and that also have the same outer peripheral shapes and may only be slightly different in height. Thus, even if the same electrical components have either the same positions of the lead elements or the same or similar whole configurations and different specifications, exemplary embodiments can facilitate distinguishing between the regular mounting positions and can prevent the electrical components from being erroneously mounted on the printed board. Also, even if the same kind electrical components have the similar configurations, exemplary embodiments can make it possible to determine whether or not the same kind electrical components are the same by verifying the respective component identifying marks against each other.

In another aspect, the component side identifying mark and board side identifying mark can be set to be sizes that can be recognized at a glance. Specifically the sizes of the marks can be set to be larger than alphabets, numerals, or the like printed on the electrical components and the printed board. The marks can comprise letters, numerals and the like and may be sized such that they can be easily recognized. Furthermore, marks can comprise simple symbols such as “◯” (circle), “Δ” (triangle), “□” (square), “⋆” (star) or the like. The component side identifying mark can be formed by coloring a surface of the electrical component and the board side identifying mark can be formed by coloring the mounting position on the printed board so that the color on the position corresponds to the color of the component side identifying mark. In some aspects, it may not be necessary to provide these identifying marks on all of the same kind electrical components and the mounting areas corresponding to the electrical components. For example, the component side identifying mark can be provided on one of two same kind electrical components and the board side identifying mark can be provided on only the mounting area corresponding to the one electrical component so that the two same kind electrical components and their mounting areas can be distinguished between them on the basis of the presence of the marks.

In other aspects, this disclosure provides a packaging board with a component side colored area provided on a surface of one of the same kind electrical components that can constitute the component side identifying mark. The printed board can be provided with a mounting area on which one of the same kind electrical components is mounted. The mounting area can be formed into a board side colored area by reversed silk screening to make the board side identifying mark.

A colored area in this aspect means an area indicated by a color different from a surface color of each of the same kind electrical components or a surface color of a resist layer on the printed board. The reversed silk screening means that characters or lines formed generally by a silk screening paint are formed into a surface color on the printed board, to which a silk printing paint is not applied, by reversing a color between a painted area, to which a silk screening paint made of a pigment ink and a thermoset resin is applied, and a non-colored area. Thus, in some embodiments it may be possible for the reversed screening and non-reversed screening to form more kinds of board side identifying marks without increasing the paint colors. Furthermore, it may be possible to cheaply form more kinds of board side identifying marks. Since the board side colored area can be different in contrast from the surface of the printed board clearly, it may be possible to readily recognize the board side identifying mark, thereby enhancing workability. It may be possible to select any color for the colored area. The color for the colored area can be set to be the same as that of a production number, a circuit sign, or the like that is silk-printed on the surface of the printed board. Thus, it may be possible to form the board side colored area at the same time in a step of making the production number, the circuit sign, or the like by silk screening.

In yet another aspect, the board side identifying mark can lie at least partially outside outer peripheral edges of the same kind component in a plan view when the same kind electrical component is mounted on said printed board.

According to the packaging board in this aspect, since the board side identifying mark may be recognized even after mounting the electrical component on the printed board, it may be possible to confirm whether or not the electrical component is mounted on the regular position by verifying the component side identifying mark against the board side identifying mark. In the case of combining the third aspect with the embodiment described above, it may be possible to automatically detect the erroneous attachment of the electrical component by reading out the component side colored area on the surface of the electrical component and the board side colored area on the printed board by utilizing an image recognition apparatus.

According to exemplary embodiments, the same kind electrical components having the same or similar configurations and the different specifications can be provided with the component side identifying marks that can be distinguished from each other and the printed board can be provided on the mounting areas for the same kind electrical components with the board side identifying marks that correspond to the component identifying marks. Thus, even if the electrical components appear to be the same or similar, it may be possible to readily recognize the same or different specifications of the electrical components on the basis of the same or different component side identifying marks. It may be possible to easily recognize the regular mounting position for the electrical component and to prevent the electrical component from being erroneously mounted on the printed board by verifying the component side identifying mark on the electrical component against the board side identifying mark on the printed board, even if the same kind electrical components have the same or similar configurations.

### BRIEF DESCRIPTION OF THE DRAWINGS

FIG. 1 is an exploded perspective view of a main part of a first embodiment of a packaging board;

FIG. 2 is a plan view of a main part of a printed board shown in FIG. 1;

FIG. 3 is a plan view of a main part of the packaging board shown in FIG. 1;

FIG. 4 is an exploded perspective view of a main part of a second embodiment of the packaging board;

FIG. 5 is a plan view of a main part of a third embodiment of the packaging board.

### DETAILED DESCRIPTION OF EMBODIMENTS

Referring now to the drawings, embodiments of a packaging board in accordance with exemplary embodiments will be described below.

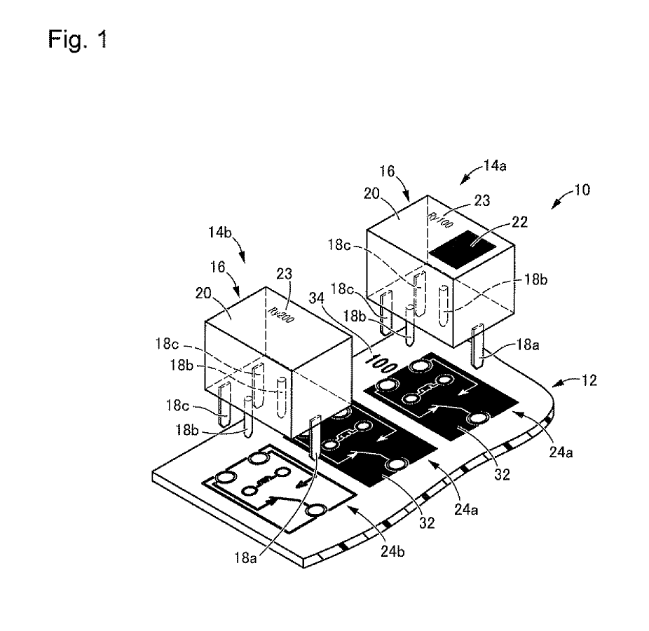

FIG. 1 shows an exploded perspective view of a main part of a first embodiment of a packaging board 10. The packaging board 10 can include a printed board 12 and a plurality of electrical components such as relays 14a and 14b mounted on the printed board 12.

The relays 14a and 14b can have the same structures as those of conventional relays. Each of the relays 14a and 14b can include a rectangular block-like main body 16, and a lead element such as a power source terminal 18a, a pair of coil terminals 18b, 18b, and a pair of contact terminals 18c, 18c. These terminals 18a to 18c can project from the main body 16. The relays 14a and 14b can have the same configurations with respect to each other. That is, the relays 14a and 14b can have the same main bodies 16 in configuration and size, the same terminals 18a to 18c in configuration, length, and position projecting from the main bodies 16 with respect to each other. Thus, although the relays 14a and 14b can have the same configurations with respect to each other, they can be formed into the same kind electrical components having different resistant values in their specifications.

The main body 16 of the one relay 14a can be provided on its upper surface 20 with a component side colored area 22. In the first embodiment, the component side colored area 22 can be a white rectangular mark (a black mark in the drawings for ease of illustration). In order to obtain visual recognition, the component side colored area 22 can be set to occupy more than one tenth ( 1/10), for example one fifth (⅕), of the whole area of the upper surface 20. The component side colored area 22 can be larger than a component model number display 23 described on the upper surface 20. The component side colored area 22 can be formed by, for example, a silk screening. The other relay 14b is not provided with the same component side colored area 22. Thus, it may be possible to discriminate between the relays 14a and 14b in accordance with the presence or absence of the component side colored area 22. Accordingly, the component side colored area 22 can define a component side identifying mark.

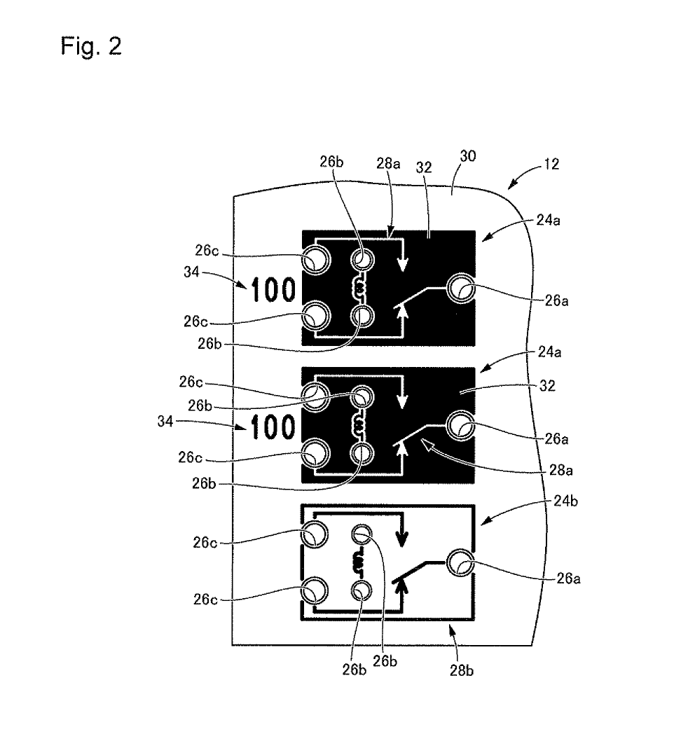

As shown in FIG. 2, the printed board 12 can be provided on its mounting areas with two relay-mounting sections 24a, 24a and a single relay-mounting section 24b. Common portions between the relay-mounting sections 24a and 24b are referred to below generally as relay-mounting sections 24.

Each relay-mounting section 24 can be provided with a plurality of through-holes 26a to 26c (five through-holes in the first embodiment) that receive the terminals 18a to 18c of the relay 14a (relay 14b). Specifically, each relay-mounting section 24 can be provided with a power source through-hole 26a that receives the power source terminal 18a of the relay 14a (14b), a pair of coil through-holes 26b, 26b that receive the coil terminals 18b, 18b, and a pair of contact through-holes 26c, 26c that receive the contacts 18c, 18c. As described above, since the relays 14a and 14b can be the same in configuration with respect to each other, the plural through-holes 26 in the relay-mounting sections 14a and 14b are same in size and position with respect to each other.

A circuit display 28b can be formed on the relay-mounting section 24b on a surface 30 of the printed board 12. The circuit display 28b can include, for example, an outer frame that surrounds an outer periphery of the relay-mounting section 24b, a coil sign for a coil that bridges the power source through-hole 26a and contact through-holes 26c, 26c, and a switch sign that indicates a connection between the power source through-hole 26a and the contact through-holes 26c, 26c. The circuit display 28b can be formed by a white silk screening paint.

In contrast, the relay-mounting section 24a can be provided with a board side colored area 32. In the first embodiment, the board side colored area 32 on the relay-mounting section 24a can be formed into a white rectangular block-like mark (black mark in the drawings). The board side colored area 32 can be formed on the relay-mounting section 24a on the surface 30 of the printed board 12 by reversing the silk screening. In order to obtain visual recognition, the board side colored area 32 can be set to occupy more than one tenth ( 1/10), for example one fifth (⅕), of the whole area of the relay-mounting section 24a. The board side colored area 32 in the first embodiment can substantially occupy a whole area of the relay-mounting section 24a and define a rectangular shape having a size slightly larger than the upper surface 20 of the relay 14a in a plan view. Thus, the board side colored area 32 can be formed as a component identifying mark by the white silk screening paint, as can be the case with the component side colored area 22 provided on the relay 14a. Thus, in the first embodiment, the board side colored area 32 can define the board side identifying mark for the relay-mounting section 24a in correspondence with the component identifying mark for the relay 14a. Since the relay-mounting section 24b is not provided with the board side colored area 32 in this embodiment, the relay-mounting section 24b can be distinguished from the relay-mounting section 24a.

Furthermore, a white a silk screening paint might not be applied to the board side colored area 32 in the relay-mounting section 24a. A color, which can remain partially on the surface 30 of the relay-mounting section 24a (for example, a green surface color on a resist layer on an ordinary printed board), can define a circuit display 28a having the same shape as that of a circuit display 28b on the relay-mounting section 24b. Since a peripheral portion around the coil sign between the coil through-holes 26b, 26b may not be colored, the coil sign can be displayed by the white silk screening paint, as may be the case with the relay-mounting section 24b.

The relay-mounting section 24a can be provided near the board side colored area 32 by means of the silk screening with a model number display 34 that indicates the relay 14a. The model number display 34 need not be the same as the model number display 23 for the relay 14a. For example, the model number display 34 can be an array of characters that partially accord with the model number display 23 for the relay 14a so long as the model number display 34 indicates a correspondence to the relay 14a.

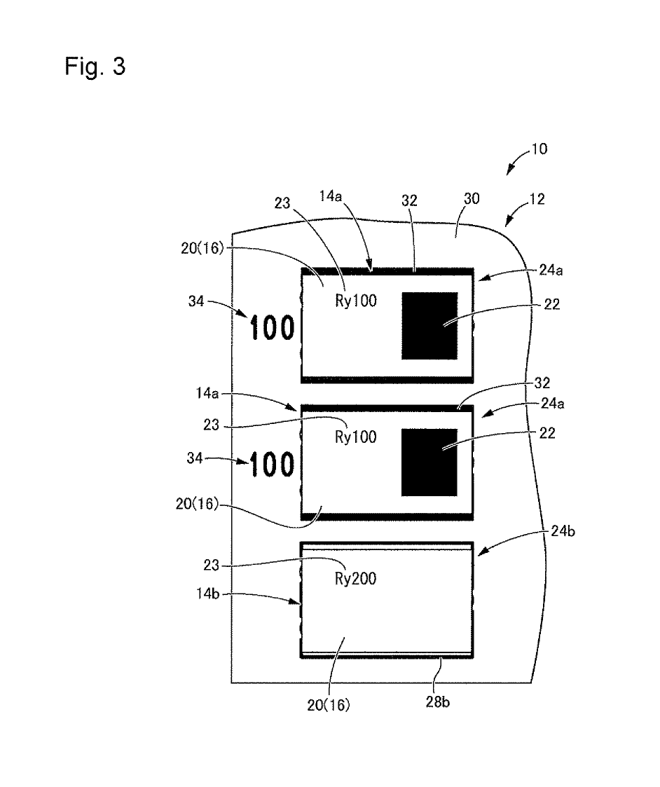

Two relay-mounting sections 24a, 24a and a single relay-mounting section 24b can be aligned with each other on the printed board 12. The two relays 14a, 14a (only one relay 14a is shown in FIG. 1) can be mounted on the two relay-mounting sections 24a, respectively. The relays 14a, 14b can be packaged on the relay-mounting sections 24a, 24b by inserting the terminals 18a to 18c into the through-holes 26a to 26c provided in the relay-mounting sections 24a, 24b, and by soldering the terminals 18a to 18c in the through-holes 26a to 26c, respectively. As shown in FIG. 3, when the relays 14a are mounted on the printed board 12, the board side colored areas 32 on the relay-mounting sections 24a may lie at least partially outside an outer peripheral edges of the relays 14a.

According to the packaging board 10 in the first embodiment, the relay 14a, which can have the same configuration but different specifications from relay 14b, can include the main body 16 provided with the component side colored area 22. Consequently, it can be possible to readily discriminate between the relays 14a and 14b in accordance with the presence of the component side colored area 22.

In the relay-mounting sections 24a and 24b, the relay-mounting section 24a, on which the relay 14a can be mounted, can be provided with the white rectangular board side colored area 32, as may be the case with the component side colored area 22 for the relay 14a. Thus, although the relay-mounting sections 24a and 24b can be provided with the through-holes 26a to 26c that are disposed at the same positions, it may be possible to readily and correctly discriminate between the relay-mounting sections 24a and 24b on the basis of the presence of the board side colored area 32. Consequently, it may be possible to correctly mount the relays 14a and 14b, which have the same configurations, onto the corresponding relay-mounting sections 24a and 24b, respectively. Accordingly, it may be possible to prevent an erroneous attachment of the relays.

The relay-mounting section 24a can be colored with white by forming the board side colored area 32 by reversing the silk screening. Thus, it may be possible to visually discriminate between the relay-mounting sections 24a and 24b readily. At the same time, since the component side colored area 22 and board side colored area 32 can be formed into the rectangular shapes, it is possible to easily discriminate between the colored areas 22 and 32 in comparison with difficult cases in discrimination of the model numbers and the like. Since the board side colored area 32 can be formed by reversing the silk screening, it may be possible to increase kinds of the board side identifying marks without increasing the number of the silk screening paints. Since the board side colored area 32 and model number display 34 on the relay-mounting section 24a and the circuit display 28 on the relay-mounting section 24b can be colored with the same white, it is possible to efficiently form the area 32 and displays 34 and 28 at the same time when the other circuit signs and the like are printed on the surface 30 of the printed board 12 by the silk screening.

Furthermore, since the board side colored area 32 may lie at least partially outside the perimeter of relay 14a in a plan view when the relay 14a is mounted on the printed board 12, it may be possible to visually recognize the board side colored area 32 even after mounting the relay 14 on the printed board 12. It may be possible to confirm whether or not the relay 14a is mounted on the regular relay-mounting section 24a on the basis of the presence of the board side colored area 32. Particularly, since the component side colored area 22 and board side colored area 32 can be displayed with white, a contrast between the main body 16 of the relay 14a and the surface 30 of the printed board 12 may be clearer and thus it may be possible for an image recognition apparatus to automatically detect the erroneous attachment. In addition, since the model number display 34 can be provided on the relay-mounting section 24a, it may be possible to more readily discriminate between the relay-mounting sections 24a and 24b on the basis of the presence of the model number display 34.

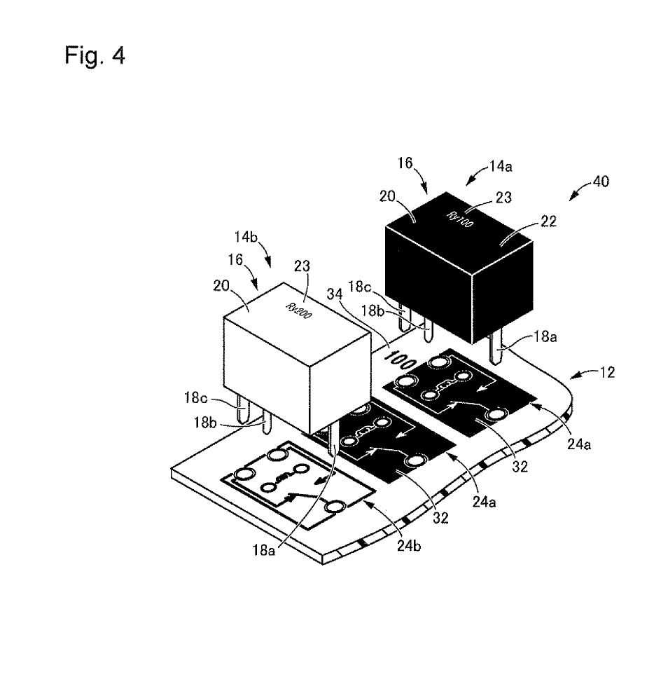

Next, FIG. 4 shows an exploded perspective view of a main part of a second embodiment of a packaging board 40. Hereinafter, descriptions of members and positions of the packaging board 40 in the second embodiment that are the same as those of the packaging board 10 in the first embodiment are omitted as appropriate by referring to the same reference numerals in the first embodiment to the second embodiment.

In the second embodiment, the whole main body 16 of the relay 14a to be mounted on the relay-mounting section 24a can be colored with white (black in FIG. 4 for ease of illustration), in correspondence with the board side colored area 32 on the relay-mounting section 24a. Thus, the whole main body 16 of the relay 14a can be provided with the component side colored area 22. The component side colored area 22 of the relay 14a in the second embodiment may be formed by producing the main body 16 of the relay 14a from a white resin material. Alternatively, the component side colored area 22 may be formed by coloring the whole main body 16 with white. In contrast, the main body 16 of the relay 14b may be colored with black (white in FIG. 4).

According to the second embodiment, since the whole main body 16 of the relay 14a can be colored with white, the main body 16 can correspond to the board side colored area 32 of the relay-mounting section 24a. Thus, it may be possible to more readily recognize a relationship in correspondence between the relay 14a and the relay-mounting section 24a.

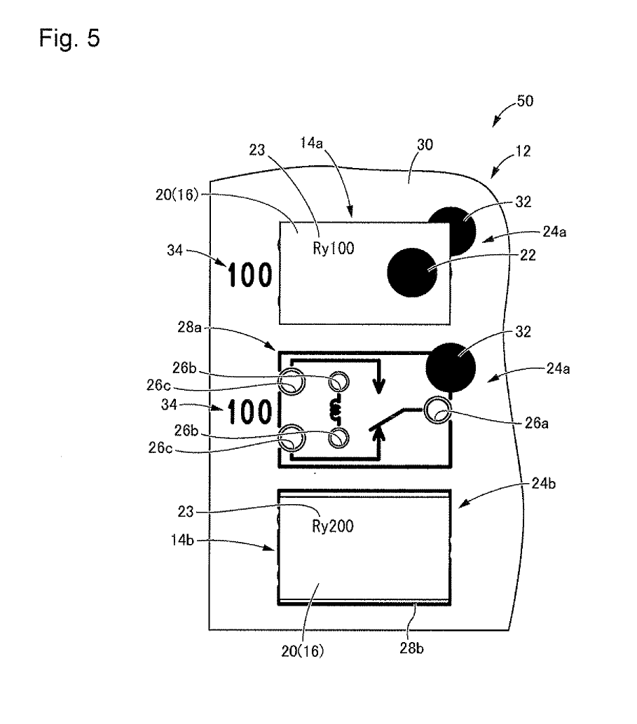

Next, FIG. 5 shows a plan view of a main part of a third embodiment of a packaging board 50. The relay-mounting section 24a can be provided as the board side colored area 32 on its corner with a white (black in FIG. 5) circular mark colored by the silk screening. The main body 16 of the relay 14a can be provided with a white (black in FIG. 5) circular component side colored area 22 in correspondence with the board side colored area 32, as may be the case with the board side colored area 32. The board side colored area 32 on the packaging board 50 can lie at least partially outside the perimeter of the relay 14a in plan view when the relay 14a is mounted on the packaging board 50.

It will be apparent from the exemplary embodiments that specific configurations of the component side colored area 22 and board side colored area 32 may be selected freely from various kinds of configurations. The board side colored area 32 may not always be provided on the whole relay-mounting section 24a.

It should be noted that the present invention is not limited to the above exemplary embodiments. For example, a plurality of colors may be selected as the component side colored area and board side colored area and the colors may be utilized to distinguish the respective specifications of the electrical components.

The colors of the component side colored area and board side colored area are not limited to white in the above embodiments and the colors may be selected from any colors. In the case where more than three electrical components having the different specifications and the same kind must be discriminated by different component side colored areas, it may be desirable to form the board side colored areas by the different colors. In embodiments where two electrical components having the different specifications and the same kind are recognized by the presence of the component side colored areas, the colors of the board side colored area and component side colored area may not be unified, since the areas can be recognized from each other in some embodiments so long as the presence of the areas can be discriminated.

A variety of same kind electrical components may be so similar that they are difficult to discriminate at a glance. The same kind electrical components are not limited to components having the same configurations provided with the same numbers of the leadelements or the same positions projecting from the main body. For example, the components may only have the same outer peripheral shapes or slightly different sizes in height. Furthermore, the same kind electrical components are not limited to the relays described above. Various kinds of electrical components to be packaged in the printed board in the prior art can be adopted. In addition, the lead elements of the electrical components are not limited to be the electrical components in which the lead elements are inserted into the through-holes. The electrical component may be a surface packaging type component in which lead elements are disposed on and soldered on lands on a surface of the printed board.

What is claimed is:

1. A packaging board having a printed board on which a plurality of electrical components are mounted, wherein:
the plurality of electrical components includes at least two electrical components of a same kind, each of the same kind components having different specifications from each other, at least one of the same kind components having a component side identifying mark that permits discrimination between the same kind components; and
the printed board is provided with mounting areas for mounting the same kind electrical components, at least one mounting area having a board side identifying mark that corresponds with the component side identifying mark.

2. A packaging board according to claim 1, wherein the component side identifying mark comprises a component side colored area provided on a surface of the at least one of the same kind electrical components, and the board side identifying mark comprises a mounting area formed into a board side colored area by reversed silk screening.

3. A packaging board according to claim 1, wherein the board side identifying mark is located at least partially outside an outer peripheral edge of a corresponding one of the plurality of electrical components in a plan view when said the component is mounted on the printed board.

4. A packaging board according to claim 2, wherein the board side identifying mark is located at least partially outside an outer peripheral edge of a corresponding one of the plurality of electrical components in a plan view when said the component is mounted on the printed board.

5. A packaging board according to claim 1, wherein the component side identifying mark comprises at least one alphanumeric symbol provided on a surface of the at least one of the same kind electrical components, and the board side identifying mark comprises the alphanumeric symbol.

6. A packaging board according to claim 1, wherein the component side identifying mark comprises at least one geometric symbol provided on a surface of the at least one of the same kind electrical components, and the board side identifying mark comprises the geometric symbol.

7. A packaging board according to claim 1, wherein the component side identifying mark comprises at least one circuit symbol provided on a surface of the at least one of the same kind electrical components, and the board side identifying mark comprises the circuit symbol.
